(19) United States
(12) Patent Application Publication
(10) Pub. No.: US 2021/0239926 A1
(43) Pub. Date: Aug. 5, 2021

(54) OPTICAL TRANSCEIVER

(71) Applicant: NEC Corporation, Tokyo (JP)

(72) Inventor: Hiroki YAMAMOTO, Tokyo (JP)

(73) Assignee: NEC Corporation, Tokyo (JP)

(21) Appl. No.: 16/973,232

(22) PCT Filed: Jun. 19, 2019
(86) PCT No.: PCT/JP2019/024268

§ 371 Date: Dec. 8, 2020

(30) Foreign Application Priority Data
Jun. 19, 2018 (JP) 2018-116068

(51) Int. Cl. G02B 6/42; H05K 7/20; H04B 10/40

(52) U.S. Cl. CPC G02B 6/4268; G02B 6/4246; H04B 10/40; G02B 6/4245; H05K 7/2039; G02B 6/424

(57) ABSTRACT

An object is to provide an optical transceiver in which optical components can be mounted at a high density and heat generated by a heat generating component can be efficiently dissipated. An optical transceiver (11) according to the present invention includes housings (4a) and (4b), a positioning member (8a) configured to position an optical component (7a) inside the housings (4a) and (4b), and a substrate (5) with a heat generating component (6a) mounted thereon, the substrate (5) being housed in the housings (4a) and (4b), in which the positioning member (8a) is configured to determine a position of the optical component (7a) inside the housings (4a) and (4b) and to thermally connect the substrate (5) to the housings (4a) and (4b).

### TECHNICAL FIELD

The present invention relates to an optical transceiver.

### BACKGROUND ART

A heat generating component, an optical component, and a positioning member are housed in a housing of an optical transceiver used for optical communication. The heat generating component is a component that generates heat when the optical transceiver is operated. When the optical component is heated to a high temperature, its characteristics may deteriorate. Therefore, it is necessary to efficiently dissipate (or radiate) the heat generated by the heat generating component.

In techniques disclosed in Patent Literatures 1 and 2, for example, heat generated by a heat generating component is dissipated to a housing through a heat dissipating member provided in a gap between the heat generating component and the housing.

Further, in techniques disclosed in Patent Literatures 3 and 4, heat generated by a heat generating component is dissipated by using a heat dissipating member which is in contact with the heat generating component.

### CITATION LIST

### Patent Literature

Patent Literature 1: Japanese Unexamined Utility Model Application Publication No. H03-083991
Patent Literature 2: Japanese Unexamined Patent Application Publication No. H09-283886
Patent Literature 3: Japanese Unexamined Patent Application Publication No. H08-148801
Patent Literature 4: Japanese Unexamined Patent Application Publication No. H05-315776

### SUMMARY OF INVENTION

### Technical Problem

In recent years, the sizes of optical transceivers used in optical communication have been increasingly reduced. In order to reduce the size of an optical transceiver, it is necessary to mount a heat generating component, an optical component, and a positioning member in a housing at a high density. However, when the heat generating component, the optical component, and the positioning member are mounted in the housing at a high density, the temperature in the housing increases and hence the characteristics of the optical component may deteriorate. Therefore, it is necessary to efficiently dissipate the heat generated by the heat generating component.

The present invention has been made in view of the above-described problem, and an object thereof is to provide an optical transceiver in which optical components can be mounted at a high density and heat generated by a heat generating component can be efficiently dissipated.

### Solution to Problem

An optical transceiver according to an aspect of the present invention includes: a housing; a positioning member configured to position an optical component inside the housing; and a substrate with a heat generating component mounted thereon, the substrate being housed in the housing. The positioning member is configured to determine a position of the optical component inside the housing and to thermally connect the substrate to the housing.

### Advantageous Effects of Invention

According to the present invention, it is possible to provide an optical transceiver in which optical components can be mounted at a high density and heat generated by a heat generating component can be efficiently dissipated.

### BRIEF DESCRIPTION OF DRAWINGS

FIG. 1 is a cross-sectional diagram of an optical transceiver according to a first example embodiment;

FIG. 2 is a cross-sectional diagram of an optical transceiver according to a second example embodiment;

FIG. 3 is a cross-sectional diagram of an optical transceiver according to a third example embodiment;

FIG. 4 is a cross-sectional diagram of an optical transceiver according to a fourth example embodiment;

FIG. 5 is a perspective view of an optical component and a positioning member; and

FIG. 6 is a plan view of an optical transceiver according to a fifth example embodiment.

### DESCRIPTION OF EMBODIMENTS

Specific example embodiments to which the present invention is applied will be described hereinafter with reference to the drawings. However, the present invention is not limited to the below-shown example embodiments. Further, to clarify the explanation, the following description and drawings are simplified as appropriate.

### First Example Embodiment

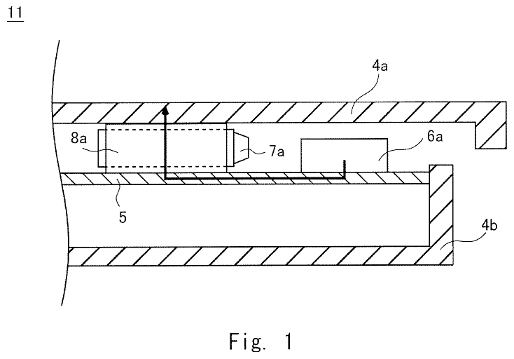

Firstly, a configuration of an optical transceiver according to a first example embodiment of the present invention will be described with reference to FIG. 1. FIG. 1 is a cross-sectional diagram of an optical transceiver according to the first example embodiment. As shown in FIG. 1, an optical transceiver 11 includes housings 4a and 4b, a substrate 5, a heat generating component 6a, an optical component 7a, and a positioning member 8a. Note that, in FIG. 1, an arrow indicates a path along which heat generated in the heat generating component 6a is conducted.

The housings 4a and 4b are a pair of housings that are arranged so as to be opposed to each other. The shapes of the housings 4a and 4b are not limited to any particular shapes. As shown in FIG. 1, for example, each of the housings 4a and 4b is a plate-like member in which a projection(s) is provided on an edge(s) thereof. The substrate 5 is housed in the housings 4a and 4b.

The substrate 5 is fixed inside the housings 4a and 4b. As shown in FIG. 1, the heat generating component 6a is mounted on the substrate 5. The heat generating component 6a is a component that generates heat when the optical transceiver 11 is operated. The heat generating component 6a is, for example, a driver for driving the optical component 7a or a processor for controlling the optical transceiver 11. The heat generating component 6a is mounted on the substrate 5 by, for example, soldering. The heat generating component 6a is preferably soldered to the substrate 5 by a reflow method.

The optical component 7a is a light-receiving element in the example shown in FIG. 1. Note that the optical component 7a may be a variable optical attenuator (VOA: Variable Optical Attenuator), a light-emitting element, a WDM filter, a laser light source, an optical fiber, or the like. The position of the optical component 7a inside the housings 4a and 4b is determined by using the positioning member 8a.

As shown in FIG. 1, the positioning member 8a is in contact with the housing 4a. The positioning member 8a may be fixed to the housing 4a or may be just in contact with the housing 4a. Further, the positioning member 8a is fixed to the substrate 5. Since the positioning member 8a is in contact with the housing 4a and is fixed to the substrate 5, it can thermally connect the substrate 5 to the housing 4a.

The positioning member 8a is fixed by using, for example, a fixing pad (not shown) provided on the substrate 5. The positioning member 8a is fixed to the fixing pad provided on the substrate 5 by, for example, soldering. In the case where the positioning member 8a is soldered, the positioning member 8a and the fixing pad are formed by using a solderable metal material such as copper.

In the case where the positioning member 8a is soldered, there is no need to form a fixing hole in the substrate 5. Therefore, components can be mounted on both sides of the substrate 5. That is, by soldering the heat generating component 6a and the positioning member 8a to the substrate 5, the area of the substrate 5 in which components can be mounted can be increased without increasing the size of the substrate 5 itself.

The positioning member 8a is preferably soldered by a reflow method. More preferably, the positioning member 8a is soldered to the substrate 5 simultaneously with the heat generating component 6a by the reflow method. By soldering the heat generating component 6a and the positioning member 8a at the same time by the reflow method, the number of processes that are required to mount the heat generating component 6a and the positioning member 8a can be reduced.

The positioning member 8a may be manually soldered to the substrate 5. In the case where the positioning member 8a is manually soldered to the substrate, for example, a shield cover that covers the optical component 7a may be provided. Further, the positioning member 8a may be fixed to the substrate 5 by a screw(s). In the case where the positioning member 8a is fixed to the substrate 5 by a screw(s), there is no need to provide a fixing pad on the substrate 5. Further, the positioning member 8a can be formed by using a material that can hardly be soldered.

The positioning member 8a may be formed by using only one material. Further, the positioning member 8a may be formed by integrating different materials with each other. Specifically, the positioning member 8a may be formed in such a manner that only an area of the positioning member 8a at which the positioning member 8a is soldered or/and areas thereof which are brought into contact with the housings 4a and 4b are formed by using a metal and the other areas thereof are formed by using a thermally-conductive resin.

When the optical transceiver 11 is operated, the heat generating component 6a generates heat. As shown in FIG. 1, the heat generated in the heat generating component 6a is conducted to the substrate 5, to the positioning member 8a, and to the housing 4a in this order. The heat conducted to the housing 4a is dissipated from the surface of the housing 4a into the atmosphere. The housing 4a may be provided with heat-dissipating fins or the like. By providing the housing 4a with heat-dissipating fins, the efficiency of the heat dissipation from the housing 4a is improved.

Note that, in the optical transceiver 11, the heat generating component 6a is preferably disposed near the place where the positioning member 8a is thermally connected to the substrate 5. Specifically, in the example shown in FIG. 1, the heat generating component 6a is preferably mounted near the place where the positioning member 8a is mounted. It is possible, by disposing the heat generating component 6a near the place where the positioning member 8a is thermally connected to the substrate 5, to shorten the length of the heat dissipation path from the heat generating component 6a to the positioning member 8a. Therefore, it is possible to efficiently conduct the heat generated by the heat generating component 6a to the housing 4a.

As described above, the sizes of optical transceivers used in optical communication have been increasingly reduced in recent years. In order to reduce the size of an optical transceiver, it is necessary to mount a heat generating component, an optical component, and a positioning member in a housing at a high density. However, when the heat generating component, the optical component, and the positioning member are mounted in the housing at a high density, the temperature in the housing increases and hence the characteristics of the optical component may deteriorate. Therefore, it is necessary to efficiently dissipate the heat generated by the heat generating component.

In view of this problem and the like, in the optical transceiver 11 according to the first example embodiment, the heat generated by the heat generating component 6a is dissipated by using the positioning member 8a. That is, the positioning member 8a, which positions the optical component 7a, also forms a heat dissipation path for dissipating the heat generated in the heat generating component 6a. Therefore, it is possible to mount the optical components at a high density and to efficiently dissipate the heat generated by the heat generating component.

Further, in the techniques disclosed Patent Literatures 1 to 4, heat generated by a heat generating component is dissipated by providing a heat dissipating member for dissipating the heat generated by the heat generating component. However, when the heat dissipating component is provided inside the housing, the number of components provided in the housing increases, thus making it difficult to reduce the size of the optical transceiver.

In contrast to this, in the optical transceiver 11 according to the first example embodiment, the heat generated in the heat generating component 6a is dissipated by forming a heat dissipation path using the positioning member 8a, instead of separately providing a heat dissipating member inside the housings 4a and 4b. Therefore, it is possible to achieve both the high-density mounting of optical components and the heat dissipation from the inside of the housing at the same time.

### Second Example Embodiment

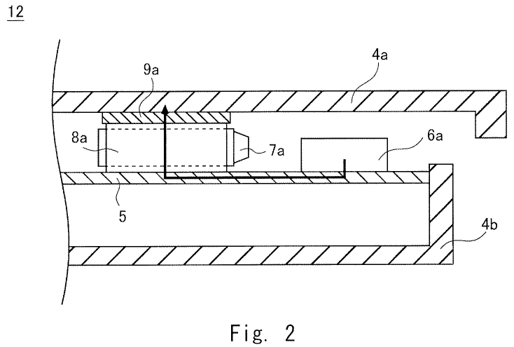

Next, a configuration of an optical transceiver according to a second example embodiment of the present invention will be described with reference to FIG. 2. FIG. 2 is a cross-sectional diagram of an optical transceiver according to the second example embodiment. As shown in FIG. 2, an optical transceiver 12 includes a thermally-conductive sheet 9a in addition to the components/structures shown in FIG. 1. Note that, in FIG. 2, an arrow indicates a path along which heat generated by the heat generating component 6a is conducted. The rest of the configuration is similar to that described in the first example embodiment, and therefore redundant descriptions thereof are omitted as appropriate.

As shown in FIG. 2, the thermally-conductive sheet 9a is disposed between the positioning member 8a and the housing 4a. The thermally-conductive sheet 9a is, for example, a cool sheet. The cool sheet has an excellent insulating property and an excellent thermal conductivity. The thermally-conductive sheet 9a may be a shield cover. The shield cover has an excellent electrical conductivity and an excellent thermal conductivity. In the case where the thermally-conductive sheet 9a is a shield cover, it is possible, by covering the positioning member 8a and the optical component 7a by the shield cover, to suppress magnetic noises of the optical component 7a.

As shown in FIG. 2, since the thermally-conductive sheet 9a is in contact with the positioning member 8a and the housing 4a, it can thermally connect the substrate 5 to the housing 4a. When the optical transceiver 12 is operated, the heat generating component 6a generates heat. As shown in FIG. 2, the heat generated by the heat generating component 6a is conducted to the substrate 5, to the positioning member 8a, to the thermally-conductive sheet 9a, and to the housing 4a in this order. The heat conducted to the housing 4a is dissipated from the surface of the housing 4a into the atmosphere. In the example shown in FIG. 2, a case in which the thermally-conductive sheet 9a is provided between the positioning member 8a and the housing 4a is shown. However, the place where the thermally-conductive sheet 9a is disposed is not limited to any particular places as long as it is disposed on the path along which the heat generated by the heat generating component 6a is conducted. For example, the thermally-conductive sheet 9a may be disposed between the positioning member 8a and the substrate 5.

The thickness of the thermally-conductive sheet 9a is changed as appropriate according to the gap between the positioning member 8a and the housing 4a. Therefore, in the optical transceiver 12, even when a plurality of positioning members 8a having different thicknesses are mounted on the substrate 5, each of the positioning members 8a can be thermally connected to the housing 4a. Therefore, in the optical transceiver 12, it is possible to dissipate the heat generated by the heat generating component 6a more efficiently. Further, the optical transceiver 12 can provide advantageous effects similar to those described in the first example embodiment.

### Third Example Embodiment

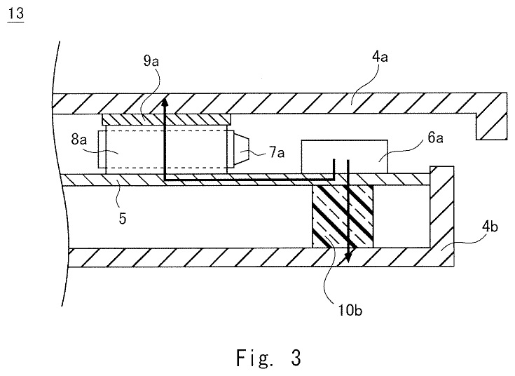

Next, a configuration of an optical transceiver according to a third example embodiment of the present invention will be described with reference to FIG. 3. FIG. 3 is a cross-sectional diagram of an optical transceiver according to the third example embodiment. As shown in FIG. 3, the optical transceiver 13 includes a thermally-conductive member 10b in addition to the components/structures shown in FIG. 2. Note that, in FIG. 3, an arrow indicates a path along which heat generated by the heat generating component 6a is conducted. The rest of the configuration is similar to those described in the first and second example embodiments, and therefore redundant descriptions thereof are omitted as appropriate.

As shown in FIG. 3, the thermally-conductive member 10b is disposed between the housing 4b and the substrate 5. The thermally-conductive member 10b can be formed of, for example, a metal material or a resin material having a high thermal conductivity. Since the thermally-conductive member 10b is in contact with the housing 4b and the substrate 5, it can thermally connect the substrate 5 and the housing 4b. When the optical transceiver 13 is operated, the heat generating component 6a generates heat. As shown in FIG. 3, a part of the heat generated by the heat generating component 6a is conducted to the substrate 5, to the thermally-conductive member 10b, and to the housing 4b in this order. The heat conducted to the housing 4b is dissipated from the surface of the housing 4b into the atmosphere.

Since the optical transceiver 13 uses both the thermally-conductive sheet 9a and the thermally-conductive member 10b, it is possible to conduct the heat generated by the heat generating component 6a to the housings 4a and 4b more efficiently than that in the optical transceiver 12 shown in FIG. 2. Further, the optical transceiver 13 can provide advantageous effects similar to those described in the first and second example embodiments.

### Fourth Example Embodiment

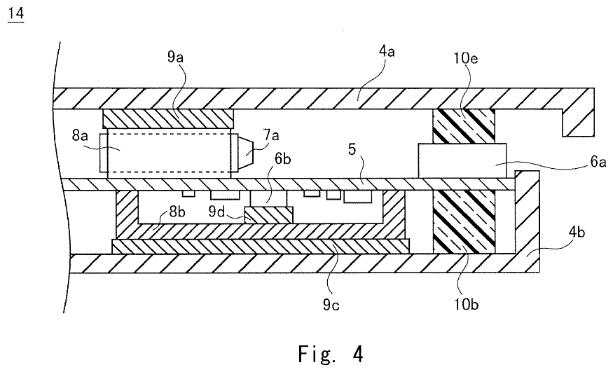

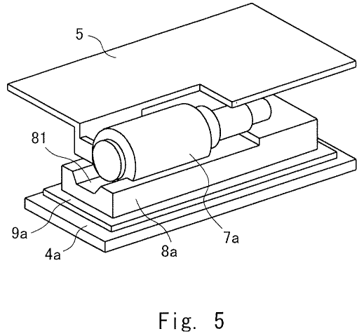

Next, a configuration of an optical transceiver according to a fourth example embodiment of the present invention will be described with reference to FIGS. 4 and 5. The fourth example embodiment according to the present invention is one similar to the optical transceiver according to the third example embodiment, but its configuration will be described hereinafter in a more detailed manner. FIG. 4 is a cross-sectional diagram of an optical transceiver according to the fourth example embodiment. FIG. 5 is a perspective view of an optical component and a positioning member.

As shown in FIG. 4, an optical transceiver 14 includes, in addition to the components/structures in FIG. 3, a heat generating component 6b, a positioning member 8b, thermally-conductive sheets 9c and 9d, and a thermally-conductive member 10e. The rest of the configuration is similar to those described in the first to third example embodiments, and therefore redundant descriptions thereof are omitted as appropriate.

In the example shown in FIG. 4, the heat generating component 6a is a driver for driving the optical component 7a. The heat generating component 6b is a processor for controlling the optical transceiver 14. As shown in FIG. 4, the heat generating component 6b is mounted on the substrate 5. The optical component 7a is a light-receiving element.

A detailed description will be given with reference to a perspective view shown in FIG. 5. A groove 81 for fixing the optical component 7a is formed in the positioning member 8a. The optical component 7a is fixed in the groove 81 of the positioning member 8a. The positioning member 8a, to which the optical component 7a is fixed, is fixed to the substrate 5. Further, the positioning member 8a is thermally connected to the housing 4a by using the thermally-conductive sheet 9a.

The positioning member 8b houses an optical fiber (not shown in FIG. 4). The optical fiber is fixed inside the positioning member 8b. As shown in FIG. 4, the positioning member 8b is mounted on the substrate 5. Therefore, when the optical fiber is fixed by using the positioning member 8b, its position inside the housings 4a and 4b is determined.

As shown in FIG. 4, the thermally-conductive sheet 9c is disposed between the housing 4b and the positioning member 8b. Since the thermally-conductive sheet 9c is in contact with the housing 4b and the positioning member 8b, it can thermally connect the positioning component 8b to the housing 4b. As shown in FIG. 4, the thermally-conductive sheet 9d is disposed between the heat generating component 6b and the positioning member 8b. Since the thermally-conductive sheet 9d is in contact with the heat generating component 6b and the positioning member 8b, it can thermally connect the heat generating component 6b to the positioning member 8b.

When the optical transceiver 14 is operated, the heat generating component 6b generates heat. As shown in FIG. 4, a part of the heat generated by the heat generating component 6b is conducted to the thermally-conductive sheet 9d, to the positioning member 8b, to the thermally-conductive sheet 9c, and to the housing 4b in this order. Further, a part of the heat generated by the heat generating component 6b is conducted to the substrate 5, to the positioning member 8a, to the thermally-conductive sheet 9a, and to the housing 4a in this order. Therefore, it is possible to dissipate the heat generated by the heat generating component 6b by using a plurality of heat dissipation paths.

As shown in FIG. 4, the thermally-conductive member 10e is disposed between the heat generating component 6a and the housing 4a. Since the thermally-conductive member 10e is in contact with the heat generating component 6a and the housing 4a, it can thermally connect the heat generating component 6a to the housing 4a. When the optical transceiver 14 is operated, the heat generating component 6a generates heat. A part of the heat generated by the heat generating component 6a is conducted to the thermally-conductive member 10e and to the housing 4a in this order. Further, a part of the heat generated by the heat generating component 6a is conducted to the housings 4a and 4b through the substrate 5, the positioning members 8a and 8b, and the thermally-conductive sheets 9a and 9c. Therefore, it is possible to dissipate the heat generated by the heat generating component 6a by using the plurality of heat dissipation paths.

The optical transceiver 14 uses the above-described plurality of heat dissipation paths at the same time, so that it is possible to efficiently dissipate the heat generated by the heat generating components 6a and 6b. Further, the optical transceiver 14 can provide advantageous effects similar to those described in the first to third example embodiments.

### Fifth Example Embodiment

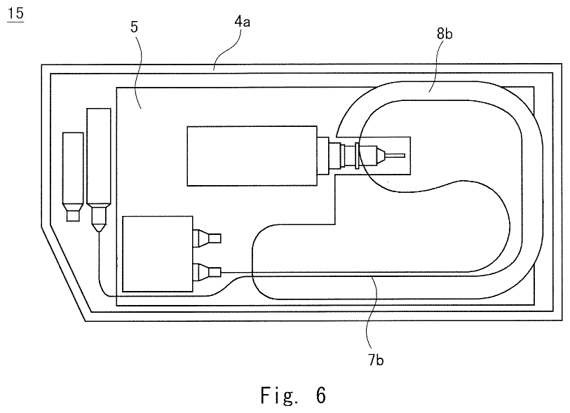

Next, a configuration of an optical transceiver according to a fifth example embodiment of the present invention will be described with reference to FIG. 6. FIG. 6 is a plan view of an optical transceiver according to the fifth example embodiment. As shown in FIG. 6, an optical transceiver 15 includes an optical component 7b in addition to the components/structures shown in FIG. 4. Note that the housing 4b shown in FIGS. 1 to 4 is not shown in FIG. 6.

The optical component 7b is an optical fiber. As shown in FIG. 6, the optical component 7b is housed in the positioning member 8b. The positioning member 8b is provided with a fixing part (not shown). The fixing part provided in the positioning member 8b is, for example, a plurality of projections. As the optical component 7b is wound around the plurality of projections, its position inside the positioning member 8b is determined.

In the optical transceiver according to the fifth example embodiment, the positioning member 8b thermally connects the substrate 5 to the housing 4b (not shown in FIG. 6). Therefore, it is possible to efficiently dissipate the heat generated by the heat generating component.

According to the invention in accordance with the above-described example embodiment, it is possible to provide an optical transceiver in which optical components can be mounted at a high density and heat generated by a heat generating component can be efficiently dissipated.

Note the present invention is not limited to the above-described example embodiments, and they may be modified as appropriate without departing from the spirit and scope of the invention.

Although the present invention is explained above with reference to example embodiments, the present invention is not limited to the above-described example embodiments. Various modifications that can be understood by those skilled in the art can be made to the configuration and details of the present invention within the scope of the invention.

This application is based upon and claims the benefit of priority from Japanese patent application No. 2018-116068, filed on Jun. 19, 2018, the disclosure of which is incorporated herein in its entirety by reference.

### REFERENCE SIGNS LIST

11, 12, 13, 14, 15 OPTICAL TRANSCEIVER
4a, 4b HOUSING
5 SUBSTRATE
6a, 6b HEAT-GENERATING COMPONENT
7a, 7b OPTICAL COMPONENT
8a, 8b POSITIONING MEMBER
81 GROOVE
9a, 9c, 9d THERMALLY-CONDUCTIVE SHEET
10b, 10e THERMALLY-CONDUCTIVE MEMBER

1. An optical transceiver comprising:
a housing;
a positioning member configured to position an optical component inside the housing; and
a substrate with a heat generating component mounted thereon, the substrate being housed in the housing, wherein
the positioning member is configured to determine a position of the optical component inside the housing and to thermally connect the substrate to the housing.

2. The optical transceiver according to claim 1, wherein the positioning member is in contact with the substrate and the housing, so that the positioning member thermally connects the substrate to the housing.

3. The optical transceiver according to claim 1, wherein
a thermally-conductive sheet is provided at least either between the positioning member and the substrate, or between the positioning member and the housing, and
the positioning member thermally connects the substrate to the housing through the thermally-conductive sheet.

4. The optical transceiver according to claim 1, wherein the positioning member is formed by using a metal material.

5. The optical transceiver according to claim 4, wherein the positioning member is soldered to the substrate.

6. The optical transceiver according to claim 1, wherein
the optical component is an optical fiber, and
the positioning member determines a position of the optical fiber inside the housing and thermally connects the substrate to the housing.

7. The optical transceiver according to claim 1, wherein
the optical component is a light-receiving element, and
the positioning member fixes the light-receiving element to the substrate and thermally connects the substrate to the housing.

8. The optical transceiver according to claim 1, further comprising a thermally-conductive member configured to thermally connect the heat generating component to the housing.

9. The optical transceiver according to claim 1, wherein the heat generating component is at least one of a driver for driving the optical component and a processor for controlling the optical transceiver.
